(19) United States
(12) Patent Application Publication
(10) Pub. No.: US 2026/0042123 A1
(43) Pub. Date: Feb. 12, 2026

(54) DEVICE, METHOD AND COMPUTER PROGRAM FOR PROCESSING OF A SURFACE OF A SUBSTRATE

(71) Applicant: Carl Zeiss SMT GmbH, Oberkochen (DE)

(72) Inventor: Daniel Rhinow, Frankfurt (DE)

(21) Appl. No.: 19/365,466

(22) Filed: Oct. 22, 2025

Related U.S. Application Data
(63) Continuation of application No. PCT/EP2024/061120, filed on Apr. 23, 2024.

(30) Foreign Application Priority Data
Apr. 25, 2023 (DE) 102023203816.1

(51) Int. Cl. B08B 3/12; B08B 1/14; B08B 5/04; B08B 13/00; G03F 1/86

(52) U.S. Cl. CPC B08B 3/12; B08B 1/14; B08B 5/04; B08B 13/00; G03F 1/86

(57) ABSTRACT

The present application relates to a device, to a method and to a computer program comprising instructions for processing of a surface of a substrate in a vacuum environment. The device includes: a fluid applicator set up to apply a fluid to a region of the surface; a manipulator set up to move the fluid and/or a particle influenced by the fluid at least to some degree on the surface of the substrate; and a positioner for relative positioning of the fluid applicator and/or of the manipulator with respect to the surface.

### CROSS-REFERENCE TO RELATED APPLICATIONS

This application is a continuation of and claims benefit under 35 U.S.C. § 120 from PCT Application PCT/EP2024/061120, filed on Apr. 23, 2024, which claims priority from German Patent Application 10 2023 203 816.1, entitled “Vorrichtung, Verfahren und Computerprogramm zum Bearbeiten einer Oberfläche eines Substrats” and filed with the German Patent and Trademark Office on Apr. 25, 2023. The entire contents of each of these earlier applications are incorporated herein by reference.

### TECHNICAL FIELD

The present invention relates to a device and to a method of processing a surface of a substrate, and to a corresponding computer program. More particularly, the processing comprises cleaning and/or purging of the surface, for example, to remove a particle from a region of the surface.

### BACKGROUND

As a result of constantly increasing integration density in microelectronics, there is a need for substrates, for example, lithographic masks, mask blanks or wafers, to have ever better surfaces. For example, lithographic masks are intended to image ever smaller structural elements into a photoresist layer of a wafer. This is likewise true of templates that are used in nanoimprint lithography. In order to meet these requirements, the exposure wavelength is being shifted to ever shorter wavelengths. At the present time, argon fluoride (ArF) excimer lasers are principally used for exposure purposes, these lasers emitting at a wavelength of 193 nm. The trend is towards ever shorter wavelengths that extend into the extreme ultraviolet (EUV) wavelength range (10 nm to 15 nm) and towards corresponding EUV masks. For example, phase masks or phase-shift masks and masks for multiple exposure can achieve a necessary increase in resolution capacity.

It is frequently the case that defects occur in the production of masks because of the ever decreasing dimensions of the structural elements. Since production is associated with high costs, defective photomasks, photolithographic masks, and likewise the templates used in nanoimprint lithography are repaired whenever possible.

In the repair of photomasks, parts of an absorber pattern that exist at positions on the mask that are not envisaged by the design may be removed. In addition, absorbing material may be deposited at positions on the mask that are free of absorbing material even though the mask design envisages absorbing pattern elements. Both types of repair processes can create debris fragments or particles that can settle at opaque, transparent or reflective sites on photomasks and cause imaging defects in lithographic exposure that are visible on a structured wafer.

A further problem is particles from the environment that settle on the surface of a mask or another substrate or on components of a photolithographic exposure system. Moreover, the handling of a mask during the process for production thereof and/or operation thereof can create particles that can settle on the mask.

There are two further difficulties in the case of photolithographic exposure systems that work with electromagnetic radiation in the EUV wavelength range. For EUV masks, there is currently no satisfactory protection (for instance a pellicle) for the surface thereof that bears structure elements. As a result, EUV masks are particularly prone to the settling of particulates on this structured surface. Secondly, a EUV radiation source typically uses a tin plasma to generate the EUV radiation (cf. Oscar O. Versolato: “Physics of laser-driven tin plasma sources of EUV radiation for nanolithography,” Plasma Sources Sci. Technol. 28 (2019) 083001, doi: 10/1088/1361-6595/ab302). Particulates from the hot plasma can be deposited on components of an EUV exposure system, especially on the optical components or elements thereof, including the EUV mask, and can impair the function thereof.

The ever decreasing structure measurements of photolithography masks are making cleaning processes increasingly difficult (cf. T. Shimomura and T. Liang: “50 nm particle removal from EUV mask blank using standard wet clean,” Proc. of SPIE Vol. 7488, S. 74882F-1-74882F-8). Moreover, as a result of the decreasing exposure wavelength, increasingly smaller foreign particles or dirt particles adhering on the surface of the mask or of an optical element of the exposure system are becoming visible on a wafer in an exposure process.

In view of ever smaller structures, tailored solutions are becoming increasingly important for processing and cleaning of masks and—more generally—substrates. In particular, it may be necessary to eliminate various defects on the same substrate with an acceptable level of cost and inconvenience. The processing of surfaces, especially the moving of particles and the lifting and/or removal of individual particles from a surface, is typically a difficult and time-consuming process. External constraints can limit the tools and treatment options available. Moreover, it can be costly and inconvenient to completely remove a particle adhering on a surface of a substrate from the substrate.

The prior art discloses approaches in the form of devices and methods for processing of surfaces: These include the local spraying of surfaces in an aftertreatment that follows substrate processing (U.S. Pat. Nos. 2,022,359 187 A1, 11,062,898 B2), the use of handheld modules for application and suction removal of cleaning liquids (U.S. Pat. No. 11,392,041 B2), and, for example, electrochemical, particle beam-based methods of local deposition or removal of material (U.S. Pat. No. 7,674,706 B2).

However, these approaches have a number of disadvantages. Moreover, they have low flexibility in the selection of possible processing tools and often require separate handling steps.

It is therefore a general aspect of the present invention to provide a device and a method that enable at least partial improvement of the processing of the surface of a substrate.

### SUMMARY

This general aspect is achieved by the aspects described herein.

A first aspect of the invention relates to a device for processing of a surface of a substrate in a vacuum environment. The device has a fluid applicator set up to apply a fluid to a region of the surface. The device further comprises a manipulator set up to move the fluid at least to some degree (out of the region). Alternatively or additionally, the manipulator may be set up to move a particle influenced by the fluid at least to some degree on the surface of the substrate (out of the region). In addition, the device comprises a positioner for relative positioning of the fluid applicator and/or the manipulator with respect to the surface.

Such a device enables targeted, efficient and fluid-based processing of the substrate surface, where a fluid is understood herein to mean a liquid. A processing operation may comprise, for example, cleaning of the substrate surface, for example, by the removal of particles, but also, for example, the removal of dark defects from lithography masks, and hence can provide higher-quality substrates, for example, masks. Typically, impracticability in vacuum environments because of the pressures that exist therein and/or inaccessibility, for example, for handheld instruments, is a limiting factor for devices and/or methods of substrate treatment, especially with regard to the usable tools and/or media, for example, liquids. Moreover, the known approaches usually follow one-stage methods of surface processing and are reliant on successful performance the first time or simple repetition thereof. The device enables the performance of an automated process in vacuum and in situ, and also makes it possible to conduct this process in a liquid-based manner in spite of a low ambient pressure. In detail, rather than simply flooding the surface with a cleaning agent as in the known prior art, at least one manipulator is used to act on the region to be processed in an additional step. This process can be effected in a controlled and local manner and can exploit synergies between successive and/or at least partly concurrent steps and hence increase the efficiency of processing. It is thus possible, by contrast with approaches based on mere washing of the surface, to specifically and efficiently remove liquids and/or particles, for example.

The vacuum environment can be created, for example, by use of a single- or multistage vacuum pump within a vacuum chamber. The vacuum chamber here may, for example, be the vacuum chamber of a (particle beam) microscope and/or of the construction in which the substrate together with the surface to be processed is naturally present in the course of its manufacture. Thus, the positioning of the device in the vacuum environment constitutes a time-, space- and labor-saving option, since the substrate can be processed, for example cleaned, directly in situ.

The fluid applicator set up to apply a fluid to a region of the surface may, for example, be a nozzle (for example, made of an electrically conductive material in order to avoid charging by a particle beam or as a result of static electricity, and/or made of an electrically nonconductive material) from which the fluid can emerge. Alternatively or additionally, the fluid applicator may include a porous material (for example, a polymer sponge) from which the fluid can emerge. In any case, the fluid applicator may be suitable for local and controlled application of the fluid, for example, within a region of 5 mm×5 mm or of 1 mm×1 mm on the surface, for example on, at and/or around a particle. The fluid may therefore be applied essentially such that it is applied within the regions mentioned, but not beyond those. The fluid may be applied to the surface in the region in a dropwise manner, as a (non-) opaque film and/or in the form of any pattern. The fluid may also be applied here outside the region. In one example, a two-dimensional film may be applied to the surface, where the covered area covers the region, but optionally also goes beyond that.

For example, the fluid may wash away a particle on the substrate surface, for example, in that the fluid, by flowing around the particle, exerts a force on the particle which is large enough to overcome the adhering interaction of the particle with the surface, such that the particle is detached and/or loosened from the surface and carried/washed away by the fluid. Additionally or alternatively, the fluid can interact with the particle, for example, in such a way that the particle is split/broken into smaller constituents. This may include, for example, at least partial dissolution and/or dispersion of the particle and/or its constituents in the fluid, in which form they are at least partly carried away. In this example, the movement of the particle may take place in a stepwise manner. In all these illustrative cases, the particle is at least partly removed.

In general, all aspects described herein in relation to a particle also relate to other contaminants, for example films, liquids, etc., other defects and/or structures on the surface of the substrate (for example, structures of lithography masks). The fluid may include a liquid, for example, that may be matched to the particle, to the application in general (for example, with regard to substrate surface, pressure in the vacuum environment, etc.), to the fluid applicator and/or to the manipulator.

The manipulator can move the fluid and/or a particle influenced by the fluid out of the region at least to some degree on the surface of the substrate. The use of the manipulator may be matched, for example, exactly to the use described herein of the fluid applicator and of the selected fluid, in order to have a greatest possible effect. The device may thus generally be set up to conduct at least two steps that are possibly matched to one another: Firstly, and as described herein, the fluid can be applied to the surface with the fluid applicator in order to display its effect there as described herein. Secondly, it is possible to simultaneously, at least partly concurrently and/or subsequently to use the manipulator in order to move the fluid and/or one or more particles influenced thereby at least to some degree, for example, out of the region. This may depend on the interaction of the fluid with the particle and can be accomplished in various ways:

The manipulator may be set up, for example, to move the particle at least to some degree on the surface without the particle ultimately departing from the surface. For example, the particle may thus be moved to a site where it has only a minor adverse effect, if any. The manipulator may alternatively, for example, remove the particle completely from the surface, for example, by sucking it away, wiping it away, lifting it away, etc.

The positioner for relative positioning of the fluid applicator and/or the manipulator relative to the surface may be set up to move and/or to rotate fluid applicator and manipulator as described herein relative to one another and/or relative to other components specified herein. In addition, the device may have, for example, further positioners that may be set up to move and/or rotate all other components specified herein, for example, relative to one another. In general, the positioning herein may relate to movement (along one or more, for example, two or three, axes) and/or rotation (about one or more, for example, two or three, axes).

In an illustrative embodiment, the positioner may be a common positioner for fluid applicator and manipulator, such that fluid applicator and manipulator in a predetermined relative position and orientation to one another are moved relative to the substrate. Alternatively or additionally, the positioner may move the substrate relative to fluid applicator and manipulator.

Fluid applicator and manipulator may optionally also be movable relative to one another with the aid of the positioner. In a further example, the positioner moves at least two of the components mentioned (fluid applicator, manipulator and substrate) relative to one another. For instance, the fluid applicator, the manipulator and/or the substrate may be positioned relative to one another in pairs in order to optimize all positions to one another.

Movement of the respective device by use of the positioner may include translational movement in space along one, two or three axes and/or rotation about one or more axes. In general, the rotation may include free rotation or restricted rotation to an angle range. Translation may likewise be spatially restricted in many examples, for example, in view of the available space within the vacuum chamber and/or the maximum deflections of the positioner.

In a further possible embodiment, fluid applicator and manipulator may, for example, be moved collectively relative to the substrate and, with regard to the relative alignment of fluid applicator and manipulator to one another, only the distance between fluid applicator and manipulator may be altered, whereas, in this example, the relative orientation of fluid applicator and manipulator to one another is invariable.

In principle, there may be one or more (identical or different) embodiments of the same components of the device, for example, two fluid applicators and/or two manipulators.

In an illustrative embodiment, the manipulator may include a suction device, an uptake device and/or a mechanical probe: If the manipulator has a suction device, for example, the at least partial movement of the fluid and/or of the particle influenced by the fluid may take place via suction of the fluid (optionally together with the particle influenced). If the manipulator has an uptake device, for example, the at least partial movement of the fluid and/or of the particle influenced by the fluid may take place in the form of uptake (for example, uptake into a sponge, at least temporary adhesion to the uptake device for lifting of the particles and/or of the fluid, etc.) of the fluid and/or of particles influenced thereby by the uptake device. In the case of a mechanical probe, the fluid and/or particles may be mechanically moved, comminuted, lifted off and/or mechanically influenced and/or moved in some other way.

This enables advantageous treatment of the surface, for example cleaning, in order to specifically remove particles and/or, for example, to correct faulty parts of a lithography mask. In particular, such a manipulator enables treatment of the surface matched to the use of the fluid.

In an illustrative embodiment for mechanical detachment of a defect and/or particle, the fluid may be used additionally or exclusively to remove broken-off material and/or shavings that have possibly arisen during the treatment of the defect and/or particle. This can be conducted, for example, in a second, separate step after the treatment of the defect and/or particle or simultaneously. The illustrative simultaneous performance of the removal of the particle to be removed and of broken-off material/shavings formed can be implemented, for example, such that the mechanical detachment is conducted in an immersive manner, i.e., in the presence of the fluid.

The suction device may include, for example, a nozzle for (local) suction of the fluid away from the surface and/or of particles dispersed and/or dissolved therein. The uptake device may include, for example, a vessel that serves for uptake of the fluid and/or of particles dispersed and/or dissolved therein (which may be connected, for example, to a suction device). Alternatively, the uptake device may include, for example, a (polymer) sponge (for example, comprising or consisting of polydimethylsiloxane) or another porous device suitable for uptake of a fluid.

In a further example, the manipulator may include a mechanical probe. Such a probe may, for example, be an atomic force microscope probe having a tip that may be set up to make contact locally with the substrate surface and/or particles thereon in order to analyze them and/or act mechanically thereon. The probe may be set up, for example, to move particles on the surface and/or to lift them off by applying force. In illustrative embodiments, imaging methods described herein may be utilized in order to observe this use of the probe in real time.

For example, the device may further comprise a means of introducing ultra- and/or megasound into the fluid present on the substrate surface.

The ultra- and/or megasound may advantageously be transmitted, for example, from the fluid to the particle. Such a use of ultra- and/or megasound may, for example, affect particles to be removed in that the ultra- and/or megasound so greatly stresses them that they split and/or break up into such small constituents and/or agitates the particle to such an extent and/or reduces the adhesion of the particle at the surface to such an extent that it becomes detached from the surface, such that it is transported away in a greatly improved manner, for example, by a fluid applied.

Such an effect may also be accompanied by heating, which promotes, for example, dispersion, dissolution in the fluid and/or detachment from the surface.

This may relate, for example, to frequencies in the range from 20 kHz to 10 MHz. A sound generator may provide this frequency and, for example, introduce it into the fluid via a mechanical probe or another suitable device, for example, directly with the aid of the fluid applicator. The frequency may be matched, for example, to the size, characteristics, composition, shape and/or position of the particle, to the amount, characteristics and/or nature of the fluid applied and/or to the nature and/or characteristics of the surface.

In one example, the fluid may be set up to at least partly mobilize and/or to at least partly take up one or more particles on the surface.

The fluid thus constitutes an advantageous option for processing of surfaces if this requires the movement of particles-even though this was originally possible only with difficulty, if at all, without damaging the surface. Thus, the use of the fluid can increase safety and reduce faults.

Possible interactions between fluid and particles may include, for example, the following mechanisms: The particle may be dissolved directly in the fluid, for example. Additionally or alternatively, the particle may be partly dissolved or chemically modified and/or the interaction between particle and surface may be altered such that it can be removed in a subsequent processing step, for example, with aid of the manipulator, for example, by subsequent use of the mechanical probe and/or by further processes, for example, etching (as described herein).

The fluid here may have the following properties: It may have low chemical reactivity with regard to the particle and may remove the particle predominantly via mechanical purging action. It may be surface-active, such that it can alter the particle-surface interaction. It may be directly reactive and lead to chemical and/or mechanical modification of the particle. It may be chemically reactive in a particle beam-induced manner. In this example, a reactive species may be generated by a particle beam. The device may have means of providing such a particle beam (e.g., an electron beam).

The fluid may additionally or alternatively contain dissolved chemical substances that are directly reactive and/or become reactive (e.g., corrosive) in a particle beam-induced manner. The illustrative properties mentioned may also occur in combination.

The effect of the fluid on the particle may comprise the following effects: The application of the fluid may be accompanied by a supply of mechanical energy to overcome or lower the binding energy between particle and surface. This can be controlled and/or influenced, for example, via the manner of supply of the fluid and/or via the manner of suction removal, for example, of the fluid. In a further example, the fluid may bring about reduction in the binding energy between particle and surface via a physical and/or chemical effect. This may subsequently facilitate/enable, for example, removal of the particle by a suitable mechanical probe.

In an illustrative embodiment, the fluid includes an ionic liquid, preferably containing: an ammonium salt, an imidazole salt, a morpholine salt, a phosphonium salt, a piperidine salt, a pyridine salt, a pyrrolidone salt and/or a sulfonium salt.

Ionic liquids are especially advantageous since they generally have a low vapor pressure and are therefore suitable for use/capable of remaining liquid even under low pressures. The use of liquids thus enabled under low pressures complements the set of tools available for treatment of substrate surfaces in vacuum environments. While conventional methods, in view of the low pressures in vacuum chambers, are mainly limited to the use of gases, for example, etch gases and deposition gases, or solids, for example mechanical probes, etc., it is possible in the present invention to use fluids in liquid form in a vacuum environment. A further advantageous aspect of ionic liquids is that they have intrinsic charges. By contrast with previously known liquids, they need not be admixed with charged particles to avoid electrostatic charges.

In general, ionic liquids may have salts that have, for example, cations such as, for example, imidazolium, pyridinium, quaternary ammonium and quaternary phosphonium, and anions such as, for example, halogen, triflate, tetrafluoroborate and hexafluorophosphate. The further advantageous characteristic properties thereof are non-flammability, non-combustibility, high thermal stability, relatively low viscosity, wide temperature ranges for liquids and high electrical conductivity.

In addition, they may be suitable for use as reaction solvent: When they are used, the dissolved substance is dissolved only by ions, with the reaction proceeding under quite different conditions than in the case of use of water or standard organic solvents. This unconventional reactivity opens up a multitude of possible modes of use in devices and/or methods as described herein.

Ammonium salt may include, for example, at least one of the following salts:
amyltriethylammonium bis(trifluoromethanesulfonyl)imide
butyltrimethylammonium bis(trifluoromethanesulfonyl)imide
benzyl(ethyl)dimethylammonium bis(trifluoromethanesulfonyl)imide
cyclohexyltrimethylammonium bis(trifluoromethanesulfonyl)imide
diethyl(methyl)propylammonium bis(fluorosulfonyl)imide
diethyl(2-methoxyethyl)methylammonium bis(fluorosulfonyl)imide
ethyl(2-methoxyethyl)dimethylammonium bis(fluorosulfonyl)imide
ethyl(2-methoxyethyl)dimethylammonium bis(trifluoromethanesulfonyl)imide
ethyl(3-methoxypropyl)dimethylammonium bis(trifluoromethanesulfonyl)imide
ethyl(dimethyl)(2-phenylethyl)ammonium bis(trifluoromethanesulfonyl)imide
methyltri-n-octylammonium bis(trifluoromethanesulfonyl)imide
tetrabutylammonium chloride
tetrabutylammonium iodide
tetrabutylammonium tetrafluoroborate
tetrahexylammonium iodide
tetraamylammonium iodide
tetra-n-octylammonium iodide
tetrabutylammonium hexafluorophosphate
tetraheptylammonium iodide
tetraamylammonium bromide
tetraamylammonium chloride
tetrabutylammonium triflate
tetrahexylammonium bromide
tetraheptylammonium bromide
tetra-n-octylammonium bromide
tetrapropylammonium chloride
tributylmethylammonium bis(trifluoromethanesulfonyl)imide
tetrabutylammonium acetate
trimethylpropylammonium bis(trifluoromethanesulfonyl)imide
tributyl(methyl)ammonium dicyanamide
tetrabutylammonium p-toluenesulfonate
tributylmethylammonium iodide

Imidazole salt may include, for example, at least one of the following salts:
1-methylimidazole hydrobromide
1-methylimidazole trifluoromethanesulfonate
1-methylimidazole bis(trifluoromethanesulfonyl)imide
1-vinylimidazolium bis(trifluoromethanesulfonyl)imide
1-allyl-3-methylimidazolium chloride
1-allyl-3-methylimidazolium bis(trifluoromethanesulfonyl)imide
1-butyl-3-methylimidazolium bromide
1-butyl-3-methylimidazolium chloride
1-butyl-3-methylimidazolium tetrafluoroborate
1-butyl-3-methylimidazolium hexafluorophosphate
1-butyl-3-methylimidazolium trifluoromethanesulfonate
1-butyl-2,3-dimethylimidazolium chloride
1-butyl-2,3-dimethylimidazolium hexafluorophosphate
1-butyl-2,3-dimethylimidazolium tetrafluoroborate
1-butyl-3-methylimidazolium bis(trifluoromethanesulfonyl)imide
1-butyl-3-methylimidazolium tetrachloroferrate
1-butyl-3-methylimidazolium iodide
1-butyl-2,3-dimethylimidazolium bis(trifluoromethanesulfonyl)imide
1-butyl-3-methylimidazolium methanesulfonate
1-butyl-3-methylimidazolium trifluoro(trifluoromethyl)borate
1-butyl-3-methylimidazolium tribromide
1-butyl-3-methylimidazolium thiocyanate
1-butyl-2,3-dimethylimidazolium triflate
3,3′-(butane-1,4-diyl)bis(1-vinyl-3-imidazolium)bis(trifluoromethanesulfonyl)imide
1-butyl-3-methylimidazolium dicyanamide
1-butyl-3-methylimidazolium tricyanomethanide
1-butyl-3-methylimidazolium trifluoroacetate
1-butyl-3-methylimidazolium methylsulfate
1-butyl-3-methylimidazolium hydrogensulfate
1-butyl-3-methylimidazolium hexafluoroantimonate
1,3-dimethylimidazolium dimethylphosphate
1,3-dimethylimidazolium chloride
1,2-dimethyl-3-propylimidazolium iodide
2,3-dimethyl-1-propylimidazolium bis(trifluoromethanesulfonyl)imide
1-decyl-3-methylimidazolium bis(trifluoromethanesulfonyl)imide
1,3-dimethylimidazolium iodide
1,3-dimethylimidazolium methylsulfate
1,3-dimethylimidazolium bis(trifluoromethanesulfonyl)imide
1-decyl-3-methylimidazolium bromide
1-decyl-3-methylimidazolium chloride
1-decyl-3-methylimidazolium tetrafluoroborate
1-dodecyl-3-methylimidazolium bromide
1-dodecyl-3-methylimidazolium bis(trifluoromethanesulfonyl)imide
1-ethyl-3-methylimidazolium chloride
1-ethyl-3-methylimidazolium hexafluorophosphate
1-ethyl-3-methylimidazolium trifluoromethanesulfonate
1-ethyl-3-methylimidazolium tetrafluoroborate
1-ethyl-3-methylimidazolium bromide
1-ethyl-3-methylimidazolium iodide
1-ethyl-3-methylimidazolium bis(trifluoromethanesulfonyl)imide
1-ethyl-3-methylimidazolium ethylsulfate
1-ethyl-3-methylimidazolium p-toluenesulfonate
1-ethyl-3-methylimidazolium dicyanamide
1-ethyl-3-methylimidazolium tetrachloroferrate
1-ethyl-2,3-dimethylimidazolium bis(trifluoromethanesulfonyl)imide
1-ethyl-3-methylimidazolium hydrogensulfate
1-ethyl-3-methylimidazolium methanesulfonate
1-ethyl-3-methylimidazolium nitrate
1-ethyl-3-methylimidazolium thiocyanate
1-ethyl-3-methylimidazolium trifluoro(trifluoromethyl)borate
1-ethyl-3-methylimidazolium acetate
3-ethyl-1-vinylimidazolium bis(trifluoromethanesulfonyl)imide
1-ethyl-3-methylimidazolium tricyanomethanide
1-ethyl-3-methylimidazolium trifluoroacetate
1-ethyl-3-methylimidazolium methylsulfate
1-ethyl-3-methylimidazolium diethylphosphate
1-hexyl-3-methylimidazolium chloride
1-hexyl-3-methylimidazolium hexafluorophosphate
1-hexyl-3-methylimidazolium tetrafluoroborate
1-hexyl-3-methylimidazolium triflate
1-hexyl-3-methylimidazolium bromide
1-(2-hydroxyethyl)-3-methylimidazolium chloride
1-(2-hydroxyethyl)-3-methylimidazolium bis(trifluoromethanesulfonyl)imide
1-hexyl-2,3-dimethylimidazolium iodide
1-hexyl-3-methylimidazolium bis(trifluoromethanesulfonyl)imide
1-(2-hydroxyethyl)-3-methylimidazolium tetrafluoroborate
1-hexyl-3-methylimidazolium iodide
1-methyl-3-propylimidazolium iodide
1-methyl-3-n-octylimidazolium bromide
1-methyl-3-n-octylimidazolium chloride
1-methyl-3-n-octylimidazolium hexafluorophosphate
1-methyl-3-n-octylimidazolium triflate
1-methyl-3-n-octylimidazolium tetrafluoroborate
1-methyl-3-propylimidazolium bromide
1-methyl-3-propylimidazolium chloride
1-methyl-3-propylimidazolium tetrafluoroborate
1-methyl-3-pentylimidazolium bromide
1-methyl-3-n-octylimidazolium bis(trifluoromethanesulfonyl)imide
1-methyl-3-propylimidazolium bis(trifluoromethanesulfonyl)imide
1-methyl-3-(4-sulfobutyl)imidazolium bis(trifluoromethanesulfonyl)imide
1-methyl-3-(4-sulfobutyl)imidazolium hydrogensulfate
1-benzyl-3-methylimidazolium chloride
1-benzyl-3-methylimidazolium tetrafluoroborate
1-benzyl-3-methylimidazolium hexafluorophosphate

Morpholine salt may include, for example, 4-ethyl-4-methylmorpholinium bromide.

Phosphonium salt may include, for example, at least one of the following salts:
tributylhexylphosphonium bromide
tributylhexadecylphosphonium bromide
tributylmethylphosphonium iodide
tributyl-n-octylphosphonium bromide
tetrabutylphosphonium bromide
tetra-n-octylphosphonium bromide
tetrabutylphosphonium tetrafluoroborate
tetrabutylphosphonium hexafluorophosphate
tetrabutylphosphonium 0,0-diethylphosphorodithioate
tributyl(2-methoxyethyl)phosphonium bis(trifluoromethanesulfonyl)imide
tributylmethylphosphonium bis(trifluoromethanesulfonyl)imide
trihexyl(tetradecyl)phosphonium dicyanamide
trihexyl(tetradecyl)phosphonium chloride
tributyl(ethyl)phosphonium diethylphosphate
tributyl(methyl)phosphonium dimethylphosphate

Piperidine salt may include, for example, at least one of the following salts:
1-butyl-1-methylpiperidinium bromide
1-butyl-1-methylpiperidinium bis(trifluoromethanesulfonyl)imide
1-methyl-1-propylpiperidinium bromide
1-methyl-1-propylpiperidinium bis(fluorosulfonyl)imide

Pyridine salt may include, for example, at least one of the following salts:
1-methylpyridinium hexafluorophosphate
1-methylpyridinium bis(trifluoromethanesulfonyl)imide
1-butylpyridinium chloride
1-butylpyridinium bromide
1-butylpyridinium hexafluorophosphate
1-butyl-4-methylpyridinium bromide
1-butyl-4-methylpyridinium hexafluorophosphate
1-butyl-3-methylpyridinium bromide
1-butylpyridinium tetrafluoroborate
1-butyl-3-methylpyridinium chloride
1-butyl-4-methylpyridinium chloride
1-butyl-4-methylpyridinium tetrafluoroborate
1-butylpyridinium bis(trifluoromethanesulfonyl)imide
1-butyl-4-methylpyridinium bis(trifluoromethanesulfonyl)imide
1-ethylpyridinium bromide
1-ethylpyridinium chloride
1-ethyl-3-methylpyridinium ethylsulfate
1-ethyl-3-(hydroxymethyl)pyridinium ethylsulfate
1-ethyl-3-methylpyridinium bis(trifluoromethanesulfonyl)imide
1-ethyl-2-methylpyridinium bromide
1-ethyl-4-methylpyridinium bromide
1-hexylpyridinium hexafluorophosphate
1-propylpyridinium chloride

Pyrrolidone salt may include, for example, at least one of the following salts:
1-allyl-1-methylpyrrolidinium bis(trifluoromethanesulfonyl)imide
1-butyl-1-methylpyrrolidinium bis(trifluoromethanesulfonyl)imide
1-butyl-1-methylpyrrolidinium chloride
1-butyl-1-methylpyrrolidinium bromide
1-butyl-1-methylpyrrolidinium bis(fluorosulfonyl)imide
1-butyl-1-methylpyrrolidinium dicyanamide
1-butyl-1-methylpyrrolidinium triflate
1-ethyl-1-methylpyrrolidinium tetrafluoroborate
1-ethyl-1-methylpyrrolidinium bromide
1-methyl-1-propylpyrrolidinium bis(trifluoromethanesulfonyl)imide
1-methyl-1-propylpyrrolidinium bis(fluorosulfonyl)imide
1-(2-methoxyethyl)-1-methylpyrrolidinium bis(fluorosulfonyl)imide
1-butyl-1-methylpyrrolidinium hexafluorophosphate
1-methyl-1-n-octylpyrrolidinium bis(trifluoromethanesulfonyl)imide
1-methyl-1-pentylpyrrolidinium bis(trifluoromethanesulfonyl)imide

Sulfonium salt may include, for example, at least one of the following salts:
trimethylsulfonium iodide
tributylsulfonium iodide
triethylsulfonium bis(trifluoromethanesulfonyl)imide

Additionally or alternatively to ionic liquids, the fluid may also comprise, for example, vacuum-compatible oils.

In one example, the fluid at a working temperature of the device, preferably room temperature, may have a vapor pressure of below 1·10⁻⁶ mbar, below 1·10⁻⁷ mbar, below 1·10⁻⁸ mbar, or below 1·10⁻⁹ mbar.

Such a low vapor pressure offers the great advantage that the fluid is in liquid form even at low pressures, for example, when used in a vacuum chamber as described herein. This means that the advantages of processing of substrates under reduced pressure (for example, avoidance of harmful atmospheric gases) can be exploited together with the advantages of the exceptional mechanical properties of liquids (for example, by comparison with gases) that are typically not available at low pressures.

The vapor pressures mentioned enable trouble-free working with liquid fluids at typical pressures in vacuum chambers, for example, in the processing of lithography masks and/or in electron microscopes.

Illustrative embodiments of the device for processing of surfaces of substrates may also comprise a device for (local) gas supply and/or (local) gas removal. The gas supplied may either find use, for example, for control of the atmosphere in general or locally, for example, as etch gas or deposition gas.

This means that the device for gas supply and/or gas removal brings several advantages:

If the gas is used to control the atmosphere (for example, via the supply of inert gases, for example, elemental gases such as, for example, nitrogen, helium, argon, neon, krypton etc., or gaseous molecular compounds such as, for example, sulfur hexafluoride), it is not necessary, for example, to lower the internal pressure of the vacuum chamber to such an extent as without inert gas, with no expectation of an adverse effect on the substrate. Instead, the inert gas creates pure ambient conditions for the substrate, whereas the comparably high pressure enables the use of a multitude of fluids, e.g., ionic liquids, in liquid form when the ambient pressure is higher than the vapor pressure of the respective fluid. This enables controlled adjustment of the fluid used, the atmosphere and the pressure to the circumstances (for example, particles to be removed, surface characteristics, etc.). In this way, it is possible to reduce the transfer of the (ionic) liquid to the gas phase; at the same time, the substrate remains in an (at least partial) vacuum. In general, a vacuum as described herein does not relate to a complete vacuum, but merely to an environment with reduced pressure compared to atmospheric pressure at the Earth's surface of about 1 bar.

If a gas is supplied, for example, for (particle beam-based) etching and/or deposition, this enables further advantageous options for controlled and/or local processing of substrate surfaces. Etch gases, for example, water vapor and/or nitrosyl chloride, may be used, for example, in order to spontaneously etch a particle wherein the main constituent is tin. The etch gases are adsorbed at the surface, such that local processing can be induced, for example, merely via the application of the particle beam (for example, a focused electron beam).

Deposition by deposition gas can be utilized, for example, in one step to modify the surface and/or to increase the surface area of the particle in order to facilitate the removal of the particle.

Useful deposition gases include the following compounds:
(metal, transition element, main group) alkyls such as cyclopentadienyl (Cp) or methylcyclopentadienyl (MeCp) trimethylplatinum (CpPtMe₃ or MeCpPtMe₃), tetramethyltin SnMe₄, trimethylgallium GaMe₃, ferrocene Cp₂Fe, bisarylchromium Ar₂Cr and other compounds of this kind.
(metal, transition element, main group) carbonyls such as chromium hexacarbonyl Cr(CO)₆, molybdenum hexacarbonyl Mo(CO)₆, tungsten hexacarbonyl W(CO)₆, dicobalt octacarbonyl Co₂(CO)₈, triruthenium dodecacarbonyl Ru₃(CO)₁₂, iron pentacarbonyl Fe(CO)₅ and other compounds of this kind.
(metal, transition element, main group) alkoxides such as tetraethoxysilane Si(OC₂H₅), tetraisopropoxytitanium Ti(OC₃H₇)₄ and other compounds of this kind.
(metal, transition element, main group) halides such as WF6, WCl6, TiCl₆, BCl₃, SiCl₄ and other compounds of this kind.
(metal, transition element, main group) complexes such as copper bis(hexafluoroacetylacetonate) Cu(C₅F₆HO₂)₂, dimethylgold trifluoroacetylacetonate Me₂Au(CsF₃H₄O₂) and other compounds of this kind.
organic compounds such as CO, CO₂, aliphatic or aromatic hydrocarbons, constituents of vacuum pump oils, volatile organic compounds and further such compounds.

In an illustrative embodiment, the device has a vacuum environment set up to generate an internal pressure of 1·10⁻⁹ to 2·10³ mbar, 1·10⁻⁷ to 1·10² mbar, 1·10⁻⁶ to 1 mbar, or 1·10⁻⁶ to 1·10⁻² mbar.

For example, the internal pressure on application of the liquid may be below 1·10² mbar, below 1 mbar, or below 1·10⁻² mbar. Alternatively or additionally, the internal pressure may be above 1·10⁻⁹, above 1·10⁻⁷ or above 1·10⁻⁶.

Working at low pressures is fundamentally advantageous since contamination of the substrates, for example, by particles in the atmosphere, can be greatly reduced under reduced pressure. Specifically in the context of the invention, especially the use of a fluid in liquid form, a suitable adjustment of the internal pressure of the vacuum chamber, in particular in accordance with the vapor pressure of the fluid, is possible since this enables the advantageous use of fluids in liquid form. For example, when the fluid to be used and the vapor pressure thereof is known, a pressure in the vacuum chamber of, for example, 105%, 110%, 115%, 120%, 130%, 140%, 150%, 200%, 300%, 400%, 500%, 1000%, 10 000% of the vapor pressure of the fluid or any intervening value or at least the values mentioned may be established in order to ensure that the fluid is in liquid form.

The vacuum can be created using, for example, a rotary vane pump, membrane pump, scroll pump, turbomolecular pump, oil diffusion pump, ion getter pump, titanium sublimation pump and/or cold trap.

In illustrative embodiments, it is possible, for example, to successively run through multiple stages using the same or different pumps in order to attain the final pressure. For example, a first pump (for example, a membrane pump) can generate an initial pressure (for example, of 0.01 to 1·10⁻³ mbar). Subsequently, in a second stage, a second pump (for example, a turbomolecular pump) can generate a high vacuum (for example, of up to 1·10⁻⁷ mbar). It is often the case that such a stepwise approach is necessary since switching-on the second pump can only be possible safely at a certain initial pressure. In addition, further stages using, for example, a third, fourth, etc., pump can generate even lower pressures.

In an illustrative embodiment, the apparatus may further comprise a particle beam source for application of a particle beam to the surface. In addition, the illustrative device may preferably include at least one detector for particle beam-based imaging of the surface.

Particle beams as described herein may generally be, for example, beams of photons (for example, in the infrared (IR), visible (VIS), ultraviolet (UV) and/or extreme ultraviolet (EUV) range), elementary particles (e.g., electrons, protons and/or neutrons), atoms, ions and/or molecules. The particle type may be different depending on the use.

The particle beam may, in illustrative embodiments, be a focused particle beam, such that the particle beam can be applied, for example, to a small area of the surface when the focal plane of the particle beam is close to the substrate surface. Focusing can be accomplished using optical elements, for example, lenses and/or mirrors, for example, for photon beams or, for example, (for example, cylinder-symmetric and/or inhomogeneous) electrical and/or magnetic fields, for example, for electron beams and/or ion beams. The particle type and energy are correlated (for example, via their de Broglie wavelength) to the resolution limit and can be matched to the required resolution.

The illustrative particle beam as described herein can be applied to the surface for processing of the surface (as described herein, for example, particle beam-induced etching and/or deposition) and/or for particle beam-based observation of the surface (for example, scanning particle microscopy).

It is additionally possible to provide detectors for observation: These may, for example, be IR/VIS/UV/EUV cameras/detectors, light microscopes, detectors for detection of backscattered and/or transmitted particles and/or detectors for detection of secondary electrons and/or other particles.

For example, the observation devices, for example, an electron beam in combination with at least one electron detector in a scanning electron microscope (SEM), may be used for observation before, during and/or after treatment (in this case a cleaning operation) of the surface. In one example, the surface is observed before and/or at the start of such a treatment, as described herein, in order to identify a particle to be removed, and fluid applicator and manipulator are positioned at a suitable position close to the particle identified. During the treatment, the particle beam and the at least one detector involved may be switched off. After the processing (for example, cleaning by removal of the particle), the surface is observed again in order to ascertain that the particle has been successfully removed or whether the treatment may need to be conducted again and/or adjusted.

In another example, the surface is observed constantly: a particle can, as described herein, be identified and removed by the applying of a fluid and use of the manipulator while the particle beam is still being applied to the surface, and the operation described herein, in which, for example, further tools may also be used as well as the fluid applicator and the manipulator, can be observed simultaneously.

However, it is also possible, for example, that the same and/or another particle beam can be used not just for imaging but alternatively or additionally for further purposes, for example, for deposition and/or for etching. An illustrative particle beam-based etching and/or deposition operation may take place, for example, in such a way that, by virtue of the focused particle beam acting locally on a fluid and/or a gas, particles and/or other structures are locally etched away or deposition is effected locally. For this purpose, particle beam and the fluids and/or gases supplied may be matched to one another.

For example, the device as described herein may be set up to process a surface of a lithography mask.

Particularly in the context of lithography masks, processing operations, especially cleaning operations, on surfaces, for example, for elimination of defects, are necessary since any defect in the lithography mask is transferred to the product produced therewith.

For example, the device may comprise a suitable holder for holding the lithography mask (and/or another substrate).

For example, the device as described herein may also be set up to detect a position of the fluid applicator and/or the manipulator.

The detection of the position, especially relative to the surface, is advantageous in order to optimally position the fluid applicator and/or the manipulator. This positioning may be crucial to accuracy, the time taken and/or the safety of the surface treatment.

The corresponding position may be measured, for example, by directing a particle beam onto the fluid applicator and/or the manipulator. For example, a particle beam may be directed onto the fluid applicator and/or the manipulator and reflected therefrom. If the reflected particle beam is detected by a suitable detector, this detector will detect, for example, a change in the signal of the reflected particle beam when the fluid applicator and/or the manipulator reaches the contact point with the surface, for example, when it is run in the direction of the surface with the positioner. The particle beam may include, for example, an electron beam and/or an ion beam and/or a photon beam.

Alternatively or additionally, the detection of the position may comprise detection of a current flow between the substrate and the fluid applicator and/or the manipulator. A suitable detector in this example will detect an abrupt increase in current flow when the fluid applicator and/or the manipulator reaches the contact point with the surface and current flow is enabled via the contact between surface and fluid applicator and/or manipulator, for example, when it is run in the direction of the surface with the positioner.

By the two illustrative procedures for detection of position, the contact point with the surface can be determined very accurately and hence the fluid applicator and/or the manipulator can be positioned exactly at the surface, for example, as close as possible to a defect/particle to be treated.

Alternatively or additionally, the position can also be detected, for example, with a distance sensor and/or with a microscope and/or a camera.

For example, the device, as described herein, may further include a device for x-ray spectroscopy of the surface and/or particles disposed thereon.

X-ray spectroscopy can in particular enable exact identification of regions, defects and/or particles to be treated on the surface. On the basis of this identification, it is possible to more accurately, quickly and safely execute other steps that the device is able to perform.

For example, x-ray spectroscopy may be energy-dispersive. Energy-dispersive x-ray spectroscopy (EDX) is based on the principle of function of using the x-radiation emitted from a region to which a particle beam is applied to determine the element composition of that region. The atoms in the region are excited by the particle beam and emit x-radiation. The wavelength of the x-radiation is element-specific and permits establishment of the composition of the region examined, for example, of a particle.

For example, it is possible by means of what is called SEM-EDX to use a combination of a scanning electron microscope and x-ray spectroscopy for element analysis on the microscopic scale. SEM-EDX is suitable in particular for local examination, for example, of individual particles.

In a further example, such a device may be used additionally or alternatively to x-ray fluorescence analysis: Excitation by x-radiation can result in the emission of x-radiation by the principle of fluorescence, which can be detected and used, for example, for large-area analysis.

Detection can be accomplished using, for example, Si(Li) detectors and/or silicon drift detectors.

If the particle is to be dissolved in the fluid, for example, exact matching of the fluid chosen to the elemental composition of the particle is crucial to the successful performance of surface processing.

Moreover, the device may comprise, for example, devices for Auger electron spectroscopy (AES), secondary ion mass spectrometry (SIMS), secondary neutral-particle mass spectrometry (SNMS), Rutherford backscattering spectroscopy (RBS) and/or low-energy ion scatter spectroscopy (LEIS).

A further aspect of the invention lies in a method of processing a surface of a substrate in a vacuum environment. The method may comprise the following steps: relative positioning of a fluid applicator and/or of a manipulator relative to the surface with a positioner; applying a fluid to a region of the surface with the fluid applicator; and moving the fluid and/or a particle influenced by the fluid at least to some degree on the surface with the manipulator.

The method constitutes an advantageous approach in which the surface can be processed in a controlled and local manner, which is of particular relevance in view of possible small structures on surfaces to be processed. For example, if small particles are to be removed, such a local processing operation may be required. Such a particle may have, for example, a diameter within a range from about 1 nm to about 100 μm. The particle may have various shapes and may interact with the substrate in any desired manner.

The steps of positioning, applying and moving may be conducted, for example, in that sequence. However, the sequence may also vary and/or the steps may be concurrent. For example, the fluid may at least partly already have been applied to the surface and/or moved/removed during the positioning of the fluid applicator and/or of the manipulator. In addition, it is possible to include further steps described herein once or more than once in the sequence of steps in this or a different sequence. In addition, all steps described herein may, for example, be repeated.

For example, in the method, the fluid applicator and/or the manipulator may be positioned relative to the surface with a positioner. For this purpose, a user may use a control unit and position the fluid applicator and/or the manipulator, for example, via an input by keyboard or mouse and/or a means of remote control. At the same time, the user may receive feedback, for example, as to the respective positions and alignments by imaging methods. For a known region to be treated, the positioner may, for example, also correspondingly position the fluid applicator and/or the manipulator in a completely or at least partly automated manner, for example, using coordinates ascertained for a site on the substrate to be processed (for example, of a particle). In one example, in which a particle is to be removed from the surface, a suitable end position for fluid applicator and manipulator is, for example, on two opposite sides of the particle, such that, for example, a flow of the fluid from the fluid applicator to the manipulator can wash away the particle. For example, fluid applicator and manipulator can thus be positioned at an equal distance and/or in an identical relative orientation to a particle, such that fluid applicator and manipulator are opposite one another on opposite sides of the particle in a mirror-image configuration at the particle position. Fluid applicator and manipulator, in other examples, may also be positioned inhomogeneously/asymmetrically in relation to the particle.

The applying of a fluid to a region of the surface with the fluid applicator can be accomplished, for example, automatically or by user input, for example, via the keyboard or mouse and/or the means of remote control. This step may take place, for example, after or even at least partly during the positioning. For example, it is possible to position the manipulator at least partly only after the applying of the fluid and/or to adjust/correct the manipulator position once again.

The fluid and/or a particle influenced by the fluid may be moved out of the region at least to some degree on the surface. For example, the movement with the manipulator may already commence (and optionally be concluded) during the applying of the fluid, or only thereafter. The manipulator may be formed as described herein. For example, when the manipulator includes a nozzle for suction removal of the fluid, for example, including the particle to be removed which is dissolved therein, it may be advantageous to maintain a constant fluid stream through the region to be treated on the surface for a certain period of time.

The methods described herein for processing of surfaces can be combined with other simultaneous and/or temporally at least partly offset methods of processing and/or cleaning of surfaces.

In one example, the method, as well as the moving of the particle influenced by the fluid, May additionally include identifying of the particle on the surface prior to the relative positioning and/or prior to the application as a further step.

The identification of a particle enables exact adjustment of all further steps to the findings relating to the identified particle, for example, size, position, critical structures on the substrate in the vicinity of the particle that are to remain undamaged, etc. This increases the efficiency, safety and speed with which the method can be conducted.

The identifying may relate not only to particles but also to other structures, for example, (incorrectly applied) parts of the structure of a lithography mask, other impurities, etc.

The method may further comprise, for example, introducing ultra- and/or megasound into the fluid present on the substrate surface.

This use of ultra- and/or megasound can bring the advantages described herein, for example simplified transporting-away of particles to be removed.

In one example, the method may further comprise mechanical action on the identified particle with the manipulator.

The mechanical action may advantageously be used in addition to the applying of the fluid in order to move the particle, for example when the action of the fluid alone cannot trigger any movement.

The manipulator here may comprise a mechanical probe, for example, capable of acting on the particle, for example, in order to move it or to lift it off/remove it from the surface. The probe may, for example, be an atomic force microscopy probe and may also be used for atomic force microscopy. Such a probe may be set up to be brought into contact with a particle to be removed, such that the particle sticks to the probe tip, and to lift and hence remove the adhering particle from the surface.

For example, the method may further comprise influencing the particle by use of the fluid, preferably by dissolving, dispersing and/or altering the particle surface.

Such influencing of the particle is advantageously in synergism with, for example, the mechanical influencing of the particle and/or the use of the manipulator for suction removal of the fluid together with the particle, since these steps can more easily move and/or remove a particle influenced as described herein.

The dissolving, dispersing and/or altering of the particle surface can be effected as described herein.

The method may further comprise, for example, generating of a controlled atmosphere within the vacuum chamber.

This step brings the advantages described herein of the low exposure of the surface with regard to fewer soil particles in the atmosphere in the vacuum chamber and the matching to the planned method.

The controlling of the atmosphere may, as described herein, comprise both the supply of suitable gases and the establishment of a desired pressure.

In addition, the method may comprise matching the internal pressure within the vacuum chamber to the fluid.

In particular, exact matching to the fluid used with regard to the vapor pressure thereof is advantageous since there is thus no great restriction either in the choice of pressure range or in that of the fluid used. This brings high flexibility in the processing of the surface and improves the efficiency and safety of the method.

The atmosphere may, for example, be altered once or more than once during the method, such that ideal conditions exist for each step.

In addition, the method may comprise supplying a gas.

As described herein, this may comprise, for example, an inert gas, a deposition gas and/or an etch gas and bring the advantages described herein.

For example, the method may comprise local supply of a deposition gas, for example, to the region. This can reduce the precision of the method and the consumption of the gases used. In general, such supply can complement the deposition method described herein, for example, for mobilizing and/or immobilizing the particle.

The local supply of the gas (for example, an etch gas or a deposition gas) allows it to display its effect locally, for example, to deposit a material or etch elements. These steps may additionally be induced by a locally applied particle beam, for example, by a focused electron beam, that the device can likewise provide.

The method may further comprise applying a particle beam to the surface, and preferably the observing of the surface by particle beam-based imaging.

The use of the particle beam, for example, for the purpose of the uses described herein, can advantageously act on the surface, particles and/or structures present thereon, the fluid, gases, etc., and promote further steps, which increases the efficiency of the method. Additionally or alternatively, it can enable particle beam-based imaging and hence constitute an important safety mechanism.

During the method, it is possible to use a uniform particle beam, for example, for observation of the surface, or it may be switched on and off once or more than once and/or different particle beams with different parameters and/or particles may be used in different and/or at least partly overlapping periods of time. In general, the method may comprise assessing/estimating the particle dose required for observation (for example, electron dose in the example of an electron beam of an electron microscope). Such an estimation may comprise the noting of the dose already applied and/or the dose to be applied. For example, this dose may be expressed relative to a dose threshold at which, for example, damage to the substrate surface, material deposition from deposition gases, etc., is to be expected.

In addition, the method may comprise directing of the particle beam onto the region for particle beam-induced deposition, preferably for enlarging the surface of an identified particle.

This may influence the particle, especially the surface of the particle, such that subsequent steps, for example, the moving of the particle through the fluid and/or the manipulator, are promoted and simplified.

An electron beam can be focused to a small focal spot having a diameter of a few nanometers or even <1 nm. An electron-beam-induced deposition process is advantageous in that the deposition reaction can be localized precisely. Moreover, an electron beam that induces a deposition process essentially does not damage the substrate, for example, the photomask on which there is a troublesome particle, for example.

For example, the particle beam-induced deposition can be conducted in such a way that a material is deposited on the surface of the particle, for example, in order to mobilize the particle. This can be effected with the aid of a deposition gas as described herein. It is alternatively conceivable that the deposition is effected with the aid of the particle beam and the fluid. The deposition can be conducted until the particle has reached its target size and the area of attack has been increased in size such that the particle can be moved, for example, by the use of a fluid.

In another example, the particle beam-induced deposition can be utilized in order to immobilize a particle, as described herein.

The method may further comprise detecting the position of the fluid applicator and/or the manipulator. This can preferably be accomplished by the directing of a particle beam onto the fluid applicator and/or the manipulator and/or the detecting of a flow of current between the substrate and the fluid applicator and/or the manipulator.

These method steps bring the abovementioned advantages, especially the exact determination of the point of contact with the surface and the associated increase in accuracy and precision of the method.

These method steps may take place, for example, solely during the positioning and/or continually/repeatedly during the processing, in order to observe the position over the entire duration of treatment and to be able to avoid and/or rapidly correct possible unwanted changes in position.

The method may further comprise, for example, analysis of the identified particle by x-ray spectroscopy and preferably the matching of the further steps at least partly on the basis of the analysis.

This improves the plannability of the steps of the method, and hence the efficiency thereof and time taken. In addition, it is possible to reduce unsuccessful surface processing attempts.

X-ray spectroscopy, especially EDX, permits conclusions as to the (elemental) composition of the region to be processed on the substrate surface.

In one example, in a first step, a particle may be identified by electron microscopy. In a subsequent step, the composition thereof can be determined by EDX. On the basis of the information obtained therefrom (for example, composition, size, position, number, surface characteristics, grain size, etc., of the particles), the subsequent steps may be planned. For example, a suitable fluid, a suitable internal pressure, suitable atmospheric gases, suitable etch gases, suitable manipulators, etc., may be used as described herein.

The method may further comprise, for example, fixing the identified particle at a suitable position on the surface.

This constitutes a suitable solution in situations in which a particle cannot be entirely removed from the surface.

For example, when a particle cannot be removed entirely from the surface but is at and/or has been moved to an unproblematic site, it may be helpful to fix it there. Particle beam-induced deposition—as described herein—can, for example, ensheath the particle there, for example, in that a material is deposited on and around the particle, and fixes it on the surface.

A further aspect of the invention relates to a computer program comprising instructions for execution of the steps of a method as described herein.

Such a computer program can at least partly automate the steps of corresponding methods. In particular, the automation of error-prone steps and/or of the steps that entail the involvement of large amounts of data can avoid errors, minimize time taken, increase precision and/or optimize the planning of the method.

For example, the computer program may be executed by a computer connected to the corresponding device. Additionally or alternatively, the computer program may be executed at least partly by a corresponding control unit that enables a user, as described herein, to at least partly control the corresponding device.

Moreover, there are possible embodiments in which the computer program assumes an assisting role, such that individual steps of the method are influenced in a partly automated manner both by the user and by the instructions in the computer program. For example, it is possible, on a user's instruction, to instruct execution of individual steps or a sequence of steps by the computer program.

In general, all functionalities that are described herein in relation to the device and/or parts thereof may also be implemented as steps of a method or as instructions of a computer program, and vice versa. It is likewise possible to translate all steps of methods into instructions in a computer program, and vice versa.

### DESCRIPTION OF DRAWINGS

The detailed description that follows describes currently preferred exemplary embodiments of the invention with reference to the drawings, wherein:

FIG. 1 shows a side view of a device according to the invention;

FIG. 2 shows a schematic side view of a device according to the invention with a manipulator in the form of an uptake device, wherein the uptake device includes a polymer sponge;

FIG. 3 shows a schematic side view of a device according to the invention with a manipulator in the form of a suction device;

FIG. 4 shows a schematic side view of a device according to the invention with a manipulator in the form of a mechanical probe;

FIG. 5 shows a schematic side view of a device according to the invention in fluid- and particle beam-based deposition and/or etching; and

FIG. 6 shows a schematic side view of a device according to the invention in gas- and particle beam-based deposition and/or etching.

### DETAILED DESCRIPTION

There follows a more detailed elucidation of currently preferred embodiments of the device of the invention and of the method of the invention for removal of at least a single particle on a substrate. The device according to the invention and the method according to the invention are described hereinafter using the example of processing in the form of particle removal. However, these are not limited to the examples described hereinafter. Instead, these may be used for processing or for removal of any types of particles, structures, materials, etc.

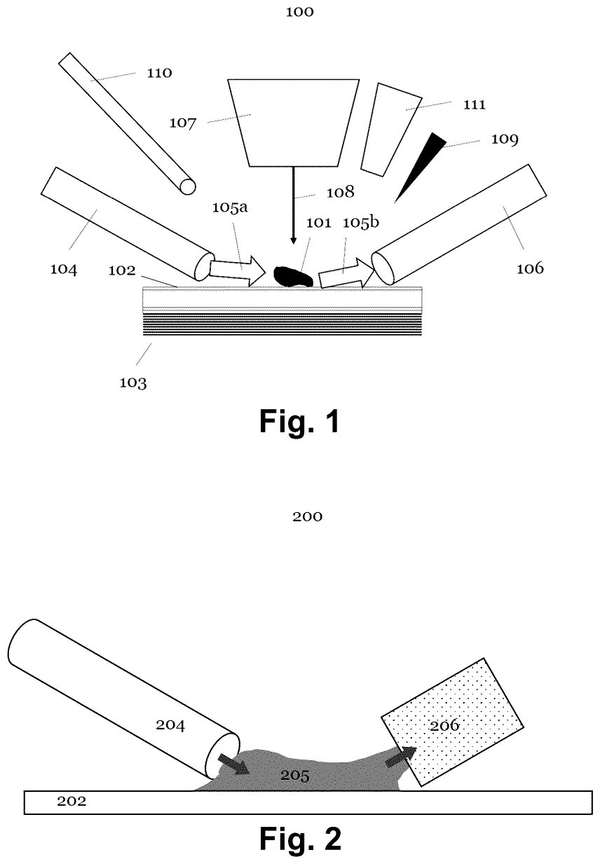

FIG. 1 shows a device 100 for processing of a surface 102 of a substrate 103.

The device has a fluid applicator 104 which, in the illustrative embodiment shown, is designed as a nozzle for application of a fluid 105a, for example, an ionic liquid as described herein. The fluid applicator 104 is in an inclined alignment at an oblique angle relative to the surface 102, and the opening of the nozzle is positioned close to the surface 102 and on the left-hand side of a particle 101. The nozzle is aligned such that the fluid 105a when it leaves the nozzle flows in the direction of the particle 101 and/or is compressed and hits the left-hand side of the particle 101. The direction of the arrow that represents the fluid 105a indicates the flow direction of the fluid 105a. The opening of the nozzle of the fluid applicator 104 and/or of the manipulator 106, when it comprises a nozzle, may have an approximately circular shape, for example, and may have a diameter, for example, of less than 1 μm (for example, in the form of a nano-nozzle and/or nano-pipette), less than 10 μm, 0.1 mm, 0.2 mm, 0.3 mm, 0.4 mm, 0.5 mm, 0.6 mm, 0.7 mm, 0.8 mm, 0.9 mm, 1 mm, 1.5 mm, less than 2 mm (or even more) or any intervening value. The nozzle opening in other examples may have, for example, comparable dimensions and/or different opening shapes, for example elongated shapes, elliptical shapes, rectangular or irregular shapes etc., for example, with comparable dimensions to those in relation to circular nozzle openings as described herein.

The illustrative particle 101 has an irregular shape and a size roughly comparable to the nozzle opening. The size of the particle 101 is not to scale, and it would be able to be (much) larger or (much) smaller. The fluid 105a can interact with the particle 101 in one of the ways described here, for example, in that it is washed away and the particle 101 is moved by the fluid 105b.

The device 100 additionally includes a manipulator 106. The fluid 105b, in the embodiment shown in schematic form, is sucked away by the manipulator 106. The illustrative manipulator 106 is designed in FIG. 1 in the form of a suction device with a nozzle for removal of the fluid 105b by suction together with particle 101. The manipulator 106 is aligned in FIG. 1, just like the fluid applicator 104, at an oblique angle relative to the surface 102 of the substrate 103. The opening of the nozzle of the manipulator 106 is directed in the direction of the right-hand side of the particle 101, such that the flow direction of the fluid 105b directs the fluid 105b towards the opening of the nozzle of the manipulator 106. The manipulator 106 may be positioned, for example, closer to the surface 102 than the fluid applicator 104. The positioning of the manipulator 106 close to the surface 102 promotes the removal of the fluid 105b by suction. It would also be possible for the manipulator 106, just like the fluid applicator 104, to be in contact with the surface 102 or to be further removed therefrom. The angles at which the manipulator 106 and the fluid applicator 104 are aligned relative to the surface 102 are slightly different. But they could also, for example, be identical or more significantly different.

The manipulator 106 and the fluid applicator 104 of the device 100 shown are positioned and aligned in the plane of the surface 102 at about a 180° angle to one another, i.e., with respect to one another, and on different sides of the particle 101. As described herein, this angle may be varied.

The fluid applicator 104 and the manipulator 106 may be in different configurations. When, for example, the fluid applicator 104 and the manipulator 106 each have a nozzle—the fluid applicator 104 one for application of the fluid 105a, and the manipulator 106 for removal of the fluid 105b by suction—the two may be opposite one another, such that the openings of the two nozzles are aligned facing one another, i.e., at a first 180° angle in a first plane (for example, parallel to the plane of the surface 102 of the substrate 103). In other illustrative embodiments, the nozzle openings may be rotated arbitrarily relative to one another, for example, at a first angle in the first plane of 175°, 170°, 165°, 160°, 155°, 150°, 145°, 140°, 135°, 130°, 125°, 120°, 115°, 110°, 105°, 100°, 95°, 90°, 85°, 80°, 75°, 70°, 65°, 60°, 55°, 50°, 45°, 40°, 35°, 30°, 25°, 20°, 15°, 10°, 5° or any other value between 0° and 180°. The nozzles may, for example, also be aligned in parallel, i.e., at a first angle of 0° in the first plane, such that the openings point in the same direction.

The nozzles may also be rotated out of the first plane (for example, the plane of the surface) in the same or a different way, for example, inclined at an oblique or sharp angle to the surface. This second angle may be, for example, 0°, 1°, 2°, 3°, 4°, 5°, 6°, 7°, 8°, 9°, 10°, 15°, 20°, 25°, 30°, 35°, 40°, 45°, 50°, 55°, 60°, 65°, 70°, 75°, 80°, 85°, 90° or intervening values.

The different illustrative arrangements may additionally also be implemented when fluid applicator 104 and/or manipulator 106 do not have any nozzles, as in the example of FIG. 1.

The device 100 additionally has a particle beam source 107 that emits a particle beam 108. The particle beam 108 is applied to the surface 102 and, in the detail, to the region of the particle 101. Typically, the particle beam 108 is focused, such that it can be applied locally, for example, in a range comparable to and/or smaller than the size of the particle 101. The particle beam source 107 may afford particles, for example, electrons, for example, with an acceleration voltage of 0.01 kV to 30 kV, which enables sub-nanometer focusing. Typical currents of the particle beam (for example, an electron beam) may, for example, be in the range from 0 to 300 nA, 3 pA to 20 nA, 100 pA to 300 nA, 1 nA to 300 nA or 1 pA to 100 pA.

The device 100 also has a mechanical probe 109. The mechanical probe 109 in FIG. 1 takes the form of an atomic force microscope tip and is set up to act mechanically on the particle 101 and/or to be used for atomic force microscopy. The probe 109 may be moved and/or detect with an accuracy of about 50 pm (for example, in the range of 10-100 pm).

In addition, the device 100 has a local gas supply 110 which may be set up, for example, for supply of an inert gas for provision of the atmosphere and/or for supply of an etch gas. The gas supply 110 is set up as a nozzle in the device 100, which, just like the other components of the device 100, can be positioned and aligned/rotated relative to the substrate 103. Particularly gases for influencing the particle 101, for example, by particle beam-based deposition, can thus be supplied locally, i.e., for example, in the vicinity of the particle 101. The nozzle may be a single nozzle that serves as a gas supply for at least one type of gas, which are supplied successively or simultaneously. In another case, there may be a set of nozzles, for example, one, two, three or more nozzles, where one nozzle in each case serves as gas supply for a respective type of gas.

The device 100 also has an optical microscope 111. Additionally or alternatively, it would also be possible for the device 100 to have at least one detector for particle beam-based imaging.

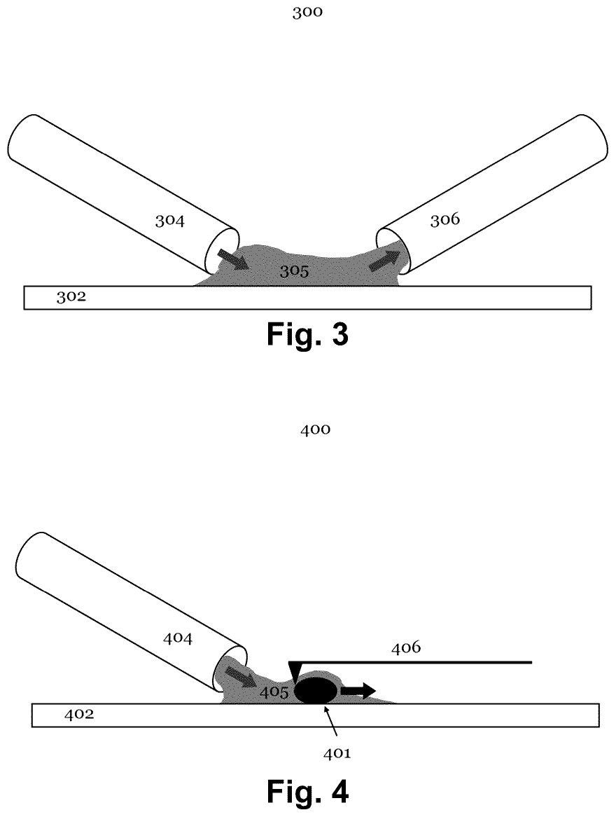

The subsequent figures, FIGS. 2 to 4, show three different embodiments of the manipulator: an uptake device (FIG. 2), a suction device (FIG. 3) and a mechanical probe (FIG. 4). The features described hereinafter can be applied generally to the manipulator according to the invention irrespective of the specific embodiment (uptake device, suction device or mechanical probe) of the respective figure:

FIG. 2 shows a schematic side view of a device 200 according to the invention with a manipulator in the form of an uptake device, wherein the uptake device includes a polymer sponge 206.

FIG. 2 shows, in detail, a schematic side view of a manipulator in the form of a polymer sponge 206 in the uptake/suction of the fluid 205 applied to the surface 202, for example, an ionic liquid. The manipulator may be movable relative to the surface 202, for example, with the aid of a corresponding positioner. The pure fluid 205, or the fluid together with dispersed and/or dissolved particles (not shown), may be taken up here by the polymer sponge 206. The grey arrows illustrate the direction of fluid flow.

The fluid 205, in FIG. 2, is applied by the fluid applicator 204 specifically to a site on the surface 202.

The polymer sponge 206 has a rectangular cross section, but may have other shapes in other possible embodiments, for example, a cross section of an irregular quadrilateral or more complex shapes. The shape may especially be matched to the surface 202.

The manipulator/polymer sponge 206 is inclined at a sharp angle to the surface 202 and disposed close to the surface 202 without being in contact therewith, but could also be positioned closer to the surface 202, such that it is in contact therewith, and/or be inclined at a different angle to the surface 202.

The polymer sponge 206 is positioned sufficiently close to the surface 202 that it is in contact with the fluid 205. Because of the adhesion force between polymer sponge 206 and fluid 205, the polymer sponge 206 can absorb the fluid 205, as shown schematically by the arrow. If the polymer sponge 206 has already at least partly absorbed the fluid 205, a cohesion force additionally acts on the fluid 205 and contributes to absorption.

FIG. 3 shows a schematic side view of a device 300 according to the invention that has a fluid applicator 304 and a manipulator in the form of a suction device 306. The fluid 305 is applied by use of the fluid applicator 304 specifically to a site on the surface 302. The suction by the suction device 306 in FIG. 3 (specifically) influences and/or controls, for example, the flow direction, flow rate, flow profile, fluid film thickness and/or further parameters of the fluid flow from the fluid applicator 304 to the suction device 306, in order to suck in the fluid 305 applied to the surface 302, for example, an ionic liquid. The grey arrows illustrate the direction of fluid flow. For example, it is possible to exploit forces resulting from liquid flow in order to at least partly move and/or wash away one or more particles influenced by the fluid 305. Adhesion forces in particular between the nozzle of the suction device 306 and the fluid volume can influence the abovementioned flow features.

The manipulator 306 may be movable relative to the surface 302, for example, with the aid of a corresponding positioner. The pure fluid 305, or the fluid together with dispersed and/or dissolved particles (not shown), may be sucked in by the suction device 306. For this purpose, the nozzle opening of the suction device may, for example, be of the same size as or larger than the particle to be removed in its original shape and/or its shape influenced by fluid 305.

FIG. 4 shows a schematic side view of a device 400 according to the invention that has a fluid applicator 404 and a manipulator in the form of a mechanical probe 406.

The fluid applicator 404 in FIG. 4 applies a fluid, for example, an ionic liquid, to a site on the surface 402 where there is a particle 401, in order then to move the particle 401 influenced by the fluid 405 and/or the fluid 405 on the surface 402 of the substrate at least to some degree (as indicated by the right-hand arrow) with the aid of the mechanical probe 406, which, in the example of FIG. 4, has an arm having a tip braced essentially at right angles, for example, an AFM tip.

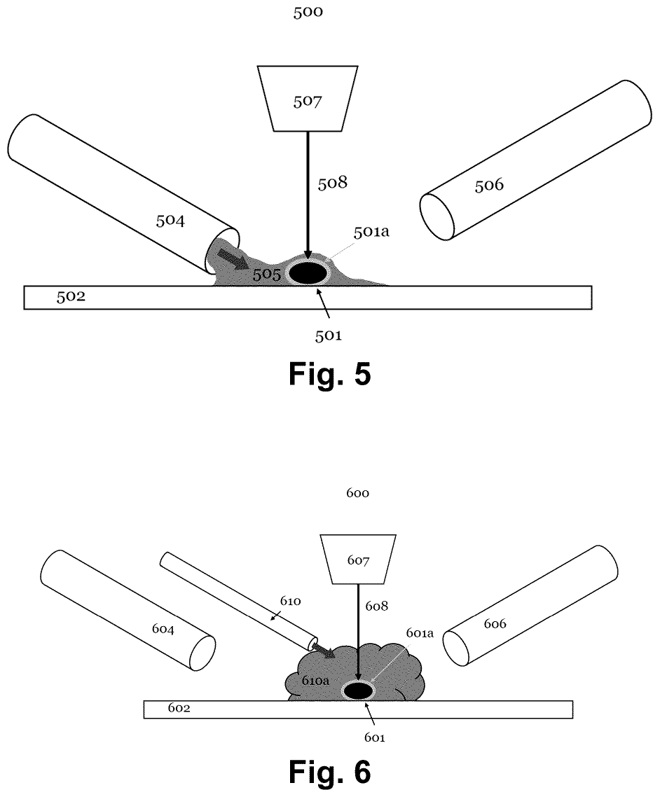

FIG. 5 shows a schematic side view of a device 500 according to the invention in fluid- and particle beam-based deposition and/or etching. The device 500 comprises a fluid applicator 504, a fluid manipulator 506 and a particle beam source 507 set up to direct a particle beam 508 as described herein onto the surface 502, and in FIG. 5 onto the particle 501 thereon. The fluid applicator 504 applies a fluid 505, for example, an ionic liquid, to a site on the surface 502 where there is a particle 501, in order to influence the particle 501 by use of the fluid 505. In detail, in FIG. 5, the particle surface 501a of the particle 501 is influenced in that material is deposited there from the fluid 505 in a particle beam-induced manner and/or in that the interaction of the fluid with the particle beam at least partly etches and/or attacks/abrades the particle surface 501a in some other way. This can enable/simplify any subsequent suction removal by use of the manipulator 506.

In FIG. 5, the manipulator 506 is spaced apart from the site of the particle 501 by use of positioners (not shown) during the deposition and/or etching, in order to enable undisrupted deposition and/or etching. It would equally be possible for the fluid applicator 504 and/or other components (possibly not shown) of the device 500 to be positioned suitably.

FIG. 6 shows a schematic side view of a device 600 according to the invention in gas- and particle beam-based deposition and/or etching. The device 600 comprises a fluid applicator 604, a fluid manipulator 606, a particle beam source 607 set up to direct a particle beam 608 as described herein onto the surface 602, and in FIG. 6 onto the particle 601 thereon, and a (local) gas supply 610. The gas supply 610 provides a gas 610a close to the surface 602 where there is a particle 601, in order to influence the particle 601 by use of the gas 605. In detail, in FIG. 5, the particle surface 601a of the particle 601 is influenced in that material is deposited there from the gas 610a in a particle beam-induced manner and/or in that the interaction of the gas 610a with the particle beam at least partly etches and/or attacks/abrades the particle surface 601a in some other way. This can enable/simplify subsequent suction removal by use of the manipulator 606, and for example, with additional use of a fluid.

What is claimed is:

1. A device for processing of a surface of a substrate in a vacuum environment, wherein the device includes:
a fluid applicator set up to apply a fluid to a region of the surface;
a manipulator set up to move the fluid and/or a particle influenced by the fluid at least to some degree on the surface of the substrate; and
a positioner for relative positioning of the fluid applicator and/or of the manipulator with respect to the surface.

2. The device of claim 1, wherein the manipulator includes a suction device, an uptake device and/or a mechanical probe.

3. The device of claim 1, further including a means of introducing ultra- and/or megasound into the fluid present on the surface.

4. The device of claim 1, wherein the fluid is set up to at least partly mobilize and/or to at least partly take up one or more particles on the surface.

5. The device of claim 1, wherein the fluid includes an ionic liquid, preferably containing: an ammonium salt, an imidazole salt, a morpholine salt, a phosphonium salt, a piperidine salt, a pyridine salt, a pyrrolidone salt and/or a sulfonium salt.

6. The device of claim 1, wherein the fluid at a working temperature, preferably room temperature, has a vapor pressure of below 1·10⁻⁶ mbar, below 1·10⁻⁷ mbar, below 1·10⁻⁸ mbar, or below 1·10⁻⁹ mbar.

7. The device of claim 1, further comprising a device for gas supply and/or gas removal.

8. The device of claim 1, wherein the device has a vacuum environment set up to generate an internal pressure of 1·10⁻⁹ to 2·10³ mbar, 1·10⁻⁷ to 1·10² mbar, 1·10⁻⁶ to 1 mbar, or 1·10⁻⁶ to 1·10⁻² mbar.

9. The device of claim 1, further comprising a particle beam source for applying a particle beam to the surface, and preferably at least one detector for particle beam-based imaging of the surface.

10. The device of claim 1, wherein the device is set up to process a surface of a lithography mask.

11. The device of claim 1, additionally set up to detect a position of the fluid applicator and/or of the manipulator, preferably by:
directing a particle beam onto the fluid applicator and/or the manipulator; and/or
detecting a flow of current between the substrate and the fluid applicator and/or the manipulator.

12. The device of claim 1, further comprising a device for x-ray spectroscopy of the surface and/or particles disposed thereon.

13. A method of processing a surface of a substrate in a vacuum environment, comprising the following steps:
relative positioning of a fluid applicator and/or of a manipulator relative to the surface with a positioner;
applying a fluid to a region of the surface with the fluid applicator; and
moving the fluid and/or a particle influenced by the fluid at least to some degree on the surface with the manipulator.

14. The method of claim 13, wherein the processing includes the moving of the particle influenced by the fluid, and wherein the method further comprises the step of: identifying the particle on the surface prior to the relative positioning and/or prior to the applying.

15. The method of claim 13, further comprising introducing ultra- and/or megasound into the fluid present on the surface.

16. The method of claim 13, further comprising mechanical action on the identified particle by the manipulator.

17. The method of claim 13, further comprising influencing the particle by use of the fluid, preferably by dissolving, dispersing and/or altering the particle surface.

18. The method of claim 13, further comprising generating a controlled atmosphere within the vacuum chamber.

19. The method of claim 18, further comprising matching the internal pressure within the vacuum chamber to the fluid.

20. The method of claim 13, further comprising supplying of a gas.

21. The method of claim 13, further comprising applying a particle beam to the surface, and preferably the observing of the surface by particle beam-based imaging.

22. The method of claim 21, further comprising directing the particle beam onto the region for particle beam-induced deposition, preferably for enlarging the surface of an identified particle.

23. The method of claim 13, further comprising detecting the position of the fluid applicator and/or of the manipulator, preferably by:
directing a particle beam onto the fluid applicator and/or the manipulator; and/or
detecting a flow of current between the substrate and the fluid applicator and/or the manipulator.

24. The method of claim 13, further comprising analyzing a particle on the surface by x-ray spectroscopy; and preferably adjusting the further method steps at least partly based on the analyzing.

25. The method of claim 13, further comprising fixing the identified particle at a suitable position on the surface.

26. A computer program comprising instructions for executing the steps of a method according to claim 13.
